(19) United States
(12) Patent Application Publication
(10) Pub. No.: US 2014/0078658 A1
(43) Pub. Date: Mar. 20, 2014

(54) DETECTION OF OLEOPHOBIC COATING

(71) Applicants: Joseph C. Rubin, San Jose, CA (US); Daniel Karraker, Cupertino, CA (US); Brett C. Ong, San Jose, CA (US)

(72) Inventors: Joseph C. Rubin, San Jose, CA (US); Daniel Karraker, Cupertino, CA (US); Brett C. Ong, San Jose, CA (US)

(21) Appl. No.: 13/622,320

(22) Filed: Sep. 18, 2012

(51) Int. Cl. H05K 13/00; G06F 1/16; G01N 21/47; B82Y 99/00; B82Y 30/00

(52) U.S. Cl. 361/679.3; 361/679.21; 118/712; 427/8; 977/755; 977/952

(57) ABSTRACT

Apparatus, systems and methods for processing covers for electronic devices are disclosed. In one embodiment, oleophobic coatings can be deposited on the covers. Oleophobicity of the coatings can be monitored. In one embodiment, glass members can pertain to cover glass for housings of the electronic devices.

### BACKGROUND OF THE INVENTION

Conventionally, small form factor devices, such as handheld electronic devices, have a display arrangement that includes various layers. The various layers include at least a display technology layer. Additionally, a sensing arrangement and/or a cover window may be disposed over the display technology layer. By way of example, the display technology layer may include or pertain to a Liquid Crystal Display (LCD) that includes a Liquid Crystal Module (LCM). The LCM generally includes an upper glass sheet and a lower glass sheet that sandwich a liquid crystal layer there between. The sensing arrangement may be a touch sensing arrangement such as those used to create a touch screen. For example, a capacitive sensing touch screen can include substantially transparent sensing points or nodes dispersed about a sheet of glass (or plastic). More generally, the touch sensing arrangement can be incorporated as any suitable part of the device including, for example, a track pad, a keyboard, a display, or combinations of these.

As the user touches the surface, however, oils and other particles from the user's fingers can be deposited on the surface. This may adversely affect the appearance of the surface, especially if information is being displayed on the surface (e.g., when the surface is the top layer of the exterior of a display).

One way to limit the amount of oils and particles deposited on the surface is to apply an oleophobic treatment to the surface. The treatment can include any suitable material having oleophobic properties. However, it can be hard to control the quality of the oleophobic material. In particular, the oleophobic material can be contaminated by exposure to air and moisture. In addition, it is possible that heating the material prior to deposition may negatively affect its oleophobic performance.

Accordingly, there is a continuing need to provide improved ways for processing covers for electronic devices.

### SUMMARY

The invention relates generally to processing covers such as glass or plastic covers. Coatings can be deposited on the covers, for example, using a cover coating deposition assembly. Further, quality of the coatings deposited on the covers can be monitored.

The invention can be implemented in numerous ways, including as a method, system, device, or apparatus. Several embodiments of the invention are discussed below.

As a system for producing cover glass for exposed surfaces of consumer electronic products, one embodiment can, for example, include at least a cover coating deposition assembly configured to deposit coatings on the covers for exposed surfaces of consumer electronic products, and a cover coating monitor configured to monitor the coatings deposited on the covers for exposed surfaces of consumer electronic products.

As a consumer electronic product, one embodiment can, for example, include at least a housing having a front surface, electrical components provided at least partially internal to the housing, the electrical components including at least a processor, a memory, and a display, the display being provided at or adjacent the front surface of the housing, and a cover provided at or over the front surface of the housing such that it is provided over the display, the cover being coated using a monitored oleophobic coating.

As a method for producing covers for exposed surfaces of consumer electronic products, one embodiment can, for example, include at least obtaining covers for the exposed surfaces of consumer electronic products, depositing coatings on the covers for exposed surfaces of consumer electronic products; and monitoring at least one of the coatings deposited on the covers for exposed surfaces of consumer electronic products.

Other aspects and advantages of the invention will become apparent from the following detailed description taken in conjunction with the accompanying drawings which illustrate, by way of example, the principles of the invention.

### BRIEF DESCRIPTION OF THE DRAWINGS

The invention will be readily understood by the following detailed description in conjunction with the accompanying drawings, wherein like reference numerals designate like structural elements, and in which:

FIG. 1 is a block diagram of a system according to one embodiment.

FIGS. 2A and 2B are diagrammatic representations of an electronic device according to one embodiment.

FIGS. 3A and 3B are a diagrammatic representation of an electronic device according to another embodiment.

FIG. 4A is a cutaway partial view of a conveyor mechanism for use in one embodiment.

FIG. 4B shows a top view of a coating deposited on a cover, along with a cutaway partial view of the conveyor mechanism shown in FIG. 4A.

FIG. 4C is a diagram depicting an analysis of scattering point density over an area of a coating having low oleophobicity.

FIG. 4D is a diagram depicting an analysis of scattering point density over an area of a coating having high oleophobicity.

FIG. 5 is a flow diagram of a process according to one embodiment.

FIG. 6 is a block diagram of a controller according to one embodiment.

### DETAILED DESCRIPTION OF EMBODIMENTS OF THE INVENTION

The invention relates generally to processing covers such as glass or plastic covers. Coatings can be deposited on the covers, for example, using a cover coating deposition assembly. Further, quality of the coatings deposited on the covers can be monitored.

Embodiments of the invention can relate to apparatus, systems and methods for processing covers for electronic devices. In one embodiment, oleophobic coatings can be deposited on the covers. Oleophobicity of the coatings can be monitored. In one embodiment, glass members can pertain to cover glass for housings of the electronic devices.

In one embodiment, the glass member may be an outer surface of a consumer electronic device. For example, the glass member may, for example, correspond to cover glass that helps form part of a display area of the electronic device (i.e., situated in front of a display either as a separate part or integrated within the display). As another example, the glass member may form a part of a housing for the consumer electronic device (e.g., may form an outer surface other than in the display area). In another embodiment, the glass member may be an inner component of a consumer electronic device. For example, the glass member can be a component glass piece of a LCD display provided internal to the housing of the consumer electronic device.

The apparatus, systems and methods are especially suitable for coating cover glass or displays (e.g., LCD displays), particularly those assembled in small form factor electronic devices such as handheld electronic devices (e.g., mobile phones, media players, personal digital assistants, remote controls, etc.). The glass can be thin in these small form factor embodiments, such as less than 3 mm, or more particularly between 0.3 and 2.5 mm. The apparatus, systems and methods can also be used for cover glass or displays for other devices including, but not limited to including, relatively larger form factor electronic devices (e.g., portable computers, tablet computers, displays, monitors, televisions, etc.). The glass can also be thin in these larger form factor embodiments, such as less than 5 mm, or more particularly between 0.3 and 3 mm.

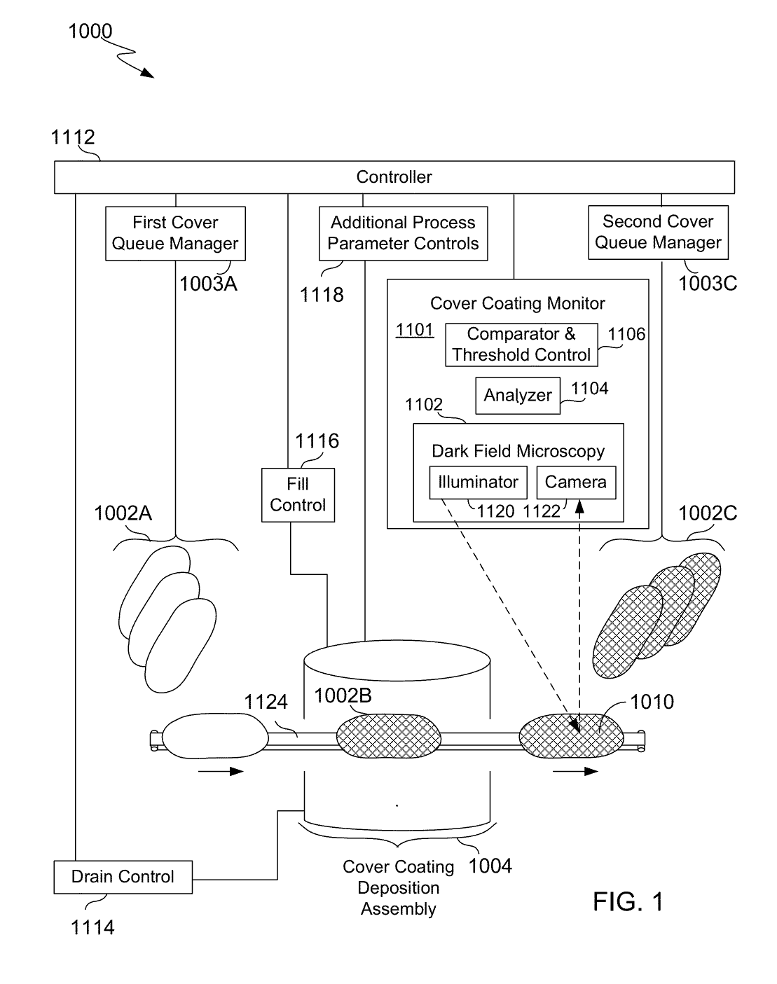

Embodiments of the invention are discussed below with reference to FIGS. 1-6. However, those skilled in the art will readily appreciate that the detailed description given herein with respect to these figures is for explanatory purposes as the invention extends beyond these limited embodiments. The illustrations provided in these figures are not necessarily drawn to scale; instead, the illustrations are presented in a manner to facilitate presentation.

FIG. 1 is a block diagram of a system 1000 according to one embodiment. System 1000 can produce covers for exposed surfaces of consumer electronic products.

FIG. 1 shows covers 1002A, 1002B, 1002C in various stages of processing. Covers 1002A to be coated can be managed by a first queue manager 1003A for organizing and/or tracking covers 1002A to be coated. Cover glass 1002C that has been coated can be managed by a second queue manager 1003C for organizing and/or tracking cover glass that has been coated.

In FIG. 1 a first notional arrow extends from the covers 1002A to be coated, and extends towards the cover 10028 being coated, so as to show processing progress of system 1000. As illustrated in FIG. 1, cover coating deposition assembly 1004 can be used for coating cover 10028.

Covers can be coated in various ways. A respective coating, for example, a respective coating comprising an oleophobic ingredient, may be deposited on each cover. For example, in one embodiment the cover coating deposition assembly 1004 can employ physical vapor deposition for depositing oleophobic coatings on the covers. Oloephobic coating depth may be approximately ten nanometers or more. In FIG. 1, cross hatching is used to depict coatings on the covers. However, typically coatings on the covers, such as oleophobic coatings on the covers, may be transparent and may appear to be invisible to the unaided eye.

Once coating is complete, cover 10028 can be removed from the cover coating deposition assembly 1004. At this point, the cover has been coated. Coatings on covers that have been coated can be monitored.

Coatings of covers can be monitored in various ways. FIG. 1 shows a coating 1010 of a cover being monitored by cover coating monitor 1101 after the cover is coated by cover coating deposition assembly 1004. In some embodiments, a respective coating, for example a respective coating comprising an oleophobic ingredient, may be monitored after each cover is coated by cover coating deposition assembly 1004.

Coatings of covers may be optically monitored by cover coating monitor 1101 using dark field microscopy 1102. Illumination of coating 1010 by illuminator 1102 is depicted in FIG. 1 by a dashed line arrow extending from illuminator 1102 to coating 1010. Illuminator 1102 may be a dark field illuminator 1102.

An electronic camera 1122 may be optically coupled with the coating 1010 through suitable microscope optics for collecting microscopic coating image data of scattering points over an area of the coating 1010. Another dashed line arrow shown in FIG. 1 as extending from the coating 1010 to electronic camera 1122 depicts illumination scattered by scattering points over the area of the coating 1010. The microscope optics of electronic camera 1122 may have strong resolving power, for example approximately twenty micron resolving power, for collecting microscopic coating image data of scattering points over the area of the coating 1010.

After monitoring of coatings, covers 1002C may be collected. In FIG. 1, a second notional arrow extends towards the covers 1002C that have been coated, so as to show processing progress of system 1000. Cross hatching highlights coatings on the covers 1002C, which have been coated.

A conveyor mechanism 1124 may convey covers as processing of system 1000 progresses. The conveyor mechanism 1124 may comprise a belt. Conveyor mechanism 1124 may have one or more predetermined geometry features, which may comprise one or more predetermined edge geometry features. For example, in embodiments where the conveyor mechanism 1124 may comprise a belt, geometry of the belt may comprise opposing belt side edge features.

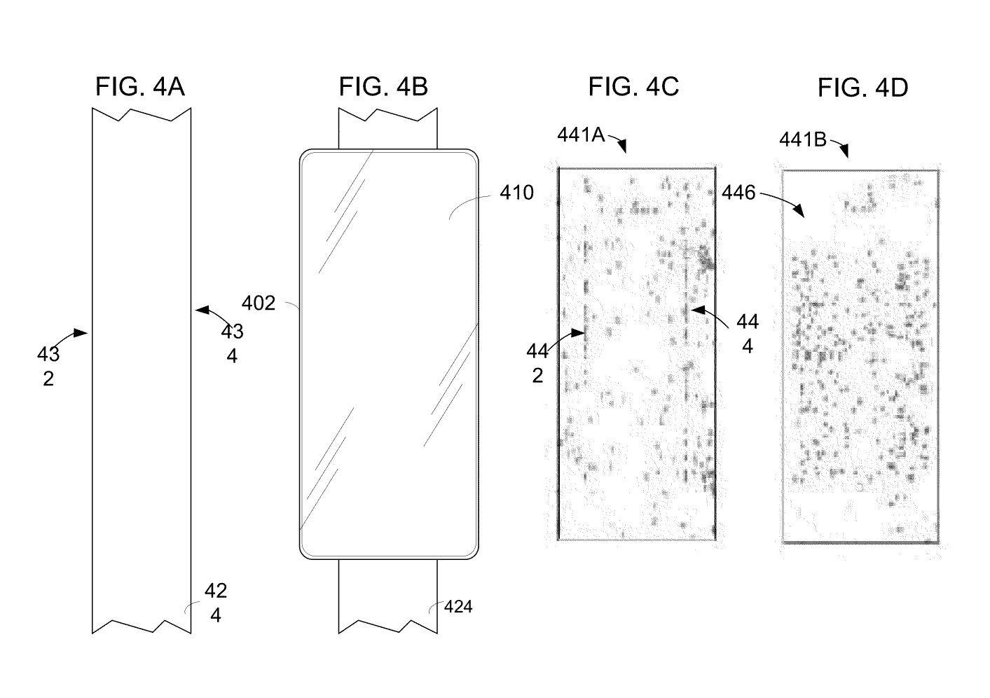

The cover coating monitor 1101 just discussed may further comprise an analyzer 1104 for analyzing the microscopic coating image data of the scattering points, and determining scattering point density over the area of coating 1010. This may comprise determining a longitudinal pattern in scattering point density over the area of at least one of the coatings, as will be discussed in greater detail subsequently herein with reference to FIG. 4C. More specifically, this may comprise determining a correlation pattern in scattering point density over the area of at least one of the coating, wherein the correlation pattern in scattering point density over the area of at least one of the coatings substantially correlates with the predetermined geometry feature of a conveyor mechanism. It is theorized that scattering point density, and in particular the longitudinal pattern and/or the correlation pattern, may be related to, and may indicate, dense presence of microscopic foreign particles or contaminants of the coating 1010. It is theorized that dense presence of microscopic foreign particles or contaminants of the coating 1010 (as may be indicated by scattering point density and/or patterning) may in turn be related to, and may indicate low oleophobicity of the coating 1010. More generally, it is theorized that dense presence of microscopic foreign particles or contaminants of the coating 1010 (as may be indicated by the scattering point density and/or patterning) may in turn be related to, and may indicate low quality or substantial quality defects of the coating 1010. In contrast, it is theorized that high oleophobicity of the coating 1010 may repel microscopic foreign particles or contaminants of the coating. It is theorized that scattering point sparseness or absence of scattering point density, and in particular absence of the longitudinal pattern and/or the correlation pattern, may indicate high oleophobicity of the coating 1010. More generally, it is theorized that sparseness of microscopic foreign particles or contaminants of the coating 1010 (as may be indicated by scattering point sparseness or absence of scattering point density and/or patterning) may in turn be related to, and may indicate high quality or substantial absence of quality defects of the coating 1010.

As will be discussed in greater detail subsequently herein with respect to FIG. 4C, low oleophobicity of the coating may be substantially related to, and may be indicated by, the longitudinal pattern in scattering point density and/or the correlation pattern in scattering point density. Low oleophobicity may be alternatively measurable by a water contact angle of approximately one hundred degrees or approximately ninety degrees or less.

As will be discussed in greater detail subsequently herein with respect to FIG. 4D, high oleophobicity of the coating may be substantially related to, and may be indicated by, scattering point sparseness and/or absence of any longitudinal pattern in scattering point density and/or absence of any correlation pattern in scattering point density. High oleophobicity may be alternatively measurable by a water contact angle of approximately one hundred degrees or more.

Analyzer 1104 may be configured to generate a signal value that is substantially related to density of scattering points over an area of at least one of the coatings. This signal value may be received by a comparator and threshold control 1106, which may be coupled with analyzer 1104.

Accordingly, the cover coating monitor 1101 may comprise comparator and threshold control 1106 for comparing a predetermined threshold value to the signal value, which is substantially related to density of scattering points over the area of at least one of the coatings. As a result of this comparison, comparator and threshold control 1106 may generate a monitor signal that is substantially related to oleophobicity of the coating. Controller 1112 may be coupled with comparator and threshold control 1106 for receiving this monitor signal.

Controller 1112 may control at least one processing parameter of the cover coating deposition assembly 1004 based at least in part on the monitoring by cover coating monitor 1101. For example, freshness of a supply of oleophobic ingredient for deposition by the cover coating deposition assembly may be at least one such processing parameter. Controller 1112 may control refreshing of the supply of oleophobic ingredient, as at least one processing parameter of the cover coating deposition assembly 1004, based at least in part on the monitoring by cover coating monitor 1101. More generally, the depositing of coatings on covers by cover coating deposition assembly 1004 may be controlled by controller 1112, based at least in part upon monitoring of coatings by cover coating monitor 1101. Controller 1112 may be adapted for generating an indicator signal when the oleophobicity of the coating provided by the cover coating deposition assembly 1004 should be adjusted based at least in part on a monitor signal indicating low oleophobicity. For example, the monitor signal indicating low oleophobicity of coating 1010 may trigger the controller 1112 to drain and refill, so as to refresh, a supply of oleophobic ingredient of the cover coating deposition assembly. This may be done using drain control 1114 and fill control 1116, which may be operatively coupled between controller 1112 and cover coating deposition assembly 1004, as shown in FIG. 1. Similarly, the monitor signal indicating low oleophobicity of the coating may trigger the controller to control other or additional process parameters of the cover coating deposition assembly 1004. This may be done using additional process parameter controls 1118, which may be operatively coupled between controller 1112 and cover coating deposition assembly 1004, as shown in FIG. 1. For example, additional process parameters of the cover coating deposition assembly 1004 may comprise pressure and/or temperature and/or duration and/or a speed of cover spin. Additional process parameter controls 1118 may comprise a pressure control and/or a temperature control and/or a timer/duration control and/or a cover spin speed control.

Controller 1112 may comprise a communication interface, processing system, storage system, and user interface. The processing system of controller 1112 may be operatively coupled to a storage system. Storage system of controller 1112 may store software and data.

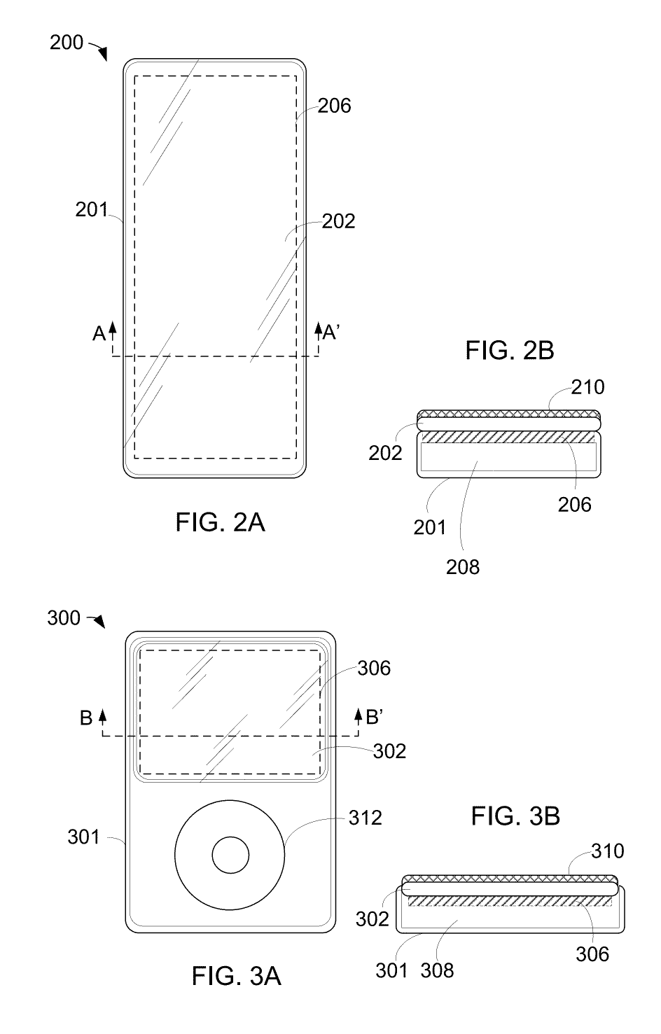

FIGS. 2A and 2B are diagrammatic representations of electronic device 200 according to one embodiment. FIG. 2A illustrates a top view for the electronic device 200, and FIG. 2B illustrates a cross-sectional side view for electronic device 200 with respect to reference line A-A′. Electronic device 200 can include housing 201 that has cover 202, such as cover glass window 202 (cover glass) with a monitored oleophobic coating 210 as a top surface.

Oleophobicity may be monitored, for example using the cover coating monitor discussed previously herein, to ensure a high oleophobicity of the monitored oleophobic coating 210. For example, the monitored oleophobic coating 210 may have high oleophobicity as measurable by a water contact angle of approximately one hundred degrees or more. Depth of the monitored oleophobic coating 210 may be approximately ten nanometers or more. For the sake of clarity in depiction using cross hatching, depth of monitored oleophobic coating 210 is shown greatly exaggerated.

Cover glass window 202 is primarily transparent so that display assembly 206 is visible through cover glass window 202. Cover glass window 202 can be strengthened chemically using ion exchange. Display assembly 206 can, for example, be positioned adjacent cover glass window 202. Housing 201 can also contain internal electrical components besides the display assembly, such as a device processor, memory, communications circuitry, etc. Display assembly 206 can, for example, include a LCD module. By way of example, display assembly 206 may include a Liquid Crystal Display (LCD) that includes a Liquid Crystal Module (LCM). In one embodiment, cover glass window 202 can be integrally formed with the LCM. Housing 201 can also include an opening 208 for containing the internal electrical components to provide electronic device 200 with electronic capabilities. In one embodiment, housing 201 need not include a bezel for cover glass window 202. Instead, cover glass window 202 can extend across the top surface of housing 201 such that the edges of cover glass window 202 can be aligned (or substantially aligned) with the sides of housing 201. The edges of cover glass window 202 can remain exposed. Although the edges of cover glass window 202 can be exposed as shown in FIGS. 2A and 2B, in alternative embodiment, the edges can be further protected. As one example, the edges of cover glass window 202 can be recessed (horizontally or vertically) from the outer sides of housing 201. As another example, the edges of cover glass window 202 can be protected by additional material placed around or adjacent the edges of cover glass window 202.

Cover glass window 202 may generally be arranged or embodied in a variety of ways. By way of example, cover glass window 202 may be configured as a protective glass piece that is positioned over an underlying display (e.g., display assembly 206) such as a flat panel display (e.g., LCD) or touch screen display (e.g., LCD and a touch layer). Alternatively, cover glass window 202 may effectively be integrated with a display, i.e., glass window may be formed as at least a portion of a display. Additionally, cover glass window 202 may be substantially integrated with a touch sensing device such as a touch layer associated with a touch screen. In some cases, cover glass window 202 with oleophobic coating 210 can serve as the outer most layer of the display.

FIGS. 3A and 3B are diagrammatic representations of electronic device 300 according to another embodiment. FIG. 3A illustrates a top view for electronic device 300, and FIG. 3B illustrates a cross-sectional side view for electronic device 300 with respect to reference line B-B′. Electronic device 300 can include housing 301 that has a cover 302, for example cover glass window 302 (cover glass) with monitored oleophobic coating 310 as a top surface. Cover glass window 302 can be strengthened chemically using ion exchange.

In the embodiment shown in FIGS. 3A and 3B, cover glass window 302 can be protected by side surfaces of housing 301. Here, cover glass window 302 does not fully extend across the top surface of housing 301. However, the top surface of side surfaces can be adjacent to, and aligned vertically with, the outer surface of cover glass window 302. Since the edges of cover glass window 302 can be rounded for enhanced strength, there may be gaps that are present between side surfaces and the peripheral edges of cover glass window 302. Gaps are typically very small given that the thickness of cover glass window 302 is thin (e.g., less than 3 mm). However, if desired, gaps can be filled by a material. The material can be plastic, rubber, metal, etc. The material can conform in the gap to render the entire front surface of electronic device 300 flush, even across gaps proximate the peripheral edges of cover glass window 302. The material filling gaps can be compliant. The material placed in gaps can implement a gasket. By filling the gaps, otherwise probably undesired gaps in housing 301 can be filled or sealed to prevent contaminates (e.g., dirt, water) from forming in the gaps. Although side surfaces can be integral with housing 301, side surface could alternatively be separate from housing 301 and, for example, operate as a bezel for cover glass window 302.

Cover glass window 302 is primarily transparent so that display assembly 306 is visible through cover glass window 302. Display assembly 306 can, for example, be positioned adjacent cover glass window 302. Housing 301 can also contain internal electrical components besides the display assembly, such as a controller (processor), memory, communications circuitry, etc. Display assembly 306 can, for example, include a LCD module. By way of example, display assembly 306 may include a Liquid Crystal Display (LCD) that includes a Liquid Crystal Module (LCM). In one embodiment, cover glass window 302 is integrally formed with the LCM. Housing 301 can also include an opening 308 for containing the internal electrical components to provide electronic device 300 with electronic capabilities.

The front surface of electronic device 300 can also include user interface control 312 (e.g., click wheel control). In this embodiment, cover glass window 302 does not cover the entire front surface of electronic device 300. Electronic device 300 essentially includes a partial display area that covers a portion of the front surface.

Cover glass window 302 may generally be arranged or embodied in a variety of ways. By way of example, cover glass window 302 may be configured as a protective glass piece that is positioned over an underlying display (e.g., display assembly 306) such as a flat panel display (e.g., LCD) or touch screen display (e.g., LCD and a touch layer). Alternatively, cover glass window 302 may effectively be integrated with a display, i.e., glass window may be formed as at least a portion of a display. Additionally, cover glass window 302 may be substantially integrated with a touch sensing device such as a touch layer associated with a touch screen. In some cases, cover glass window 302 with monitored coating layer 310 can serve as the outer most layer of the display.

As noted above, the electronic device can be a handheld electronic device or a portable electronic device. Chemical strengthening can serve to enable cover glass to be not only thin but also adequately strong. Since handheld electronic devices and portable electronic devices are mobile, they are potentially subjected to various different impact events and stresses that stationary devices are not subjected to. As such, the invention is well suited for implementation of monitored oleophobic coating on glass surfaces for handheld electronic devices or portable electronic devices that are designed to be thin.

The chemically strengthened glass (e.g., cover glass or cover glass windows) is particularly useful for thin glass applications. For example, the thickness of chemically strengthened cover glass can be between about 0.5-2.5 mm. In other embodiments, the strengthening is suitable for glass products whose thickness is less than about 2 mm, or even thinner than about 1 mm, or still even thinner than about 0.6 mm.

In one embodiment, the size of the cover glass depends on the size of the associated electronic device. For example, with handheld electronic devices, the size of the cover glass is often not more than five (5) inches (about 12.7 cm) diagonal. As another example, for portable electronic devices, such as smaller portable computers or tablet computers, the size of the cover glass is often between four (4) (about 10.2 cm) and twelve (12) inches (about 30.5 cm) diagonal. As still another example, for portable electronic devices, such as full size portable computers, displays (including televisions) or monitors, the size of the cover glass is often between ten (10) (about 25.4 cm) and twenty (20) inches (about 50.8 cm) diagonal or even larger.

However, it should be appreciated that with larger screen sizes, the thickness of the glass layers may need to be greater. The thickness of the glass layers may need to be increased to maintain planarity of the larger glass layers. While the displays can still remain relatively thin, the minimum thickness can increase with increasing screen size. For example, the minimum thickness of the cover glass can correspond to about 0.3 mm for small handheld electronic devices, about 0.5 mm for smaller portable computers or tablet computers, and about 1.0 mm or more for full size portable computers, displays or monitors, again depending on the size of the screen. However, more generally, the thickness of the cover glass can depend on the application and/or the size of electronic device.

FIG. 4A is a cutaway partial view of conveyor mechanism 424 for use in one embodiment. As discussed previously herein with reference to FIG. 1, the conveyor mechanism may comprise a belt. As shown in FIG. 4A, conveyor mechanism 424 may have one or more predetermined geometry features 432, 434, which may comprise one or more predetermined edge geometry features 432, 434. For example, in embodiments where the conveyor mechanism 424 may comprise a belt, geometry of the belt may comprise opposing belt side edge features 432, 434.

FIG. 4B shows a top view of a coating 410 deposited on a cover 402, along with a cutaway partial view of the conveyor mechanism 424 shown in FIG. 4A. FIG. 4C is a diagram depicting an analysis 441A of scattering point density over an area of a coating having low oleophobicity. The analysis 441A depicted in diagram FIG. 4C may be performed by the analyzer discussed previously herein with respect to FIG. 1. The analyzer of the cover coating monitor may analyze microscopic coating image data of illuminated scattering points, and may determine scattering point density over the area of the coating 410 of cover 402 shown in FIG. 4B. As shown in FIG. 4C, this may comprise determining longitudinal patterns 442, 444 in scattering point density over the area of the coating. More specifically, this may comprise determining correlation patterns 442, 444 in scattering point density over the area of the coating, wherein the correlation patterns 442, 444 in scattering point density over the area of the coating shown in FIG. 4C substantially correlate with the predetermined geometry features 432, 434 of the conveyor mechanism shown in FIG. 4A.

Low oleophobicity of the coating may be substantially related to, and may be indicated by, the longitudinal patterns 442, 444 in scattering point density and/or the correlation patterns 442, 444 in scattering point density, as depicted in FIG. 4C. Low oleophobicity may be alternatively measurable by a water contact angle of approximately one hundred degrees or approximately ninety degrees or less.

FIG. 4D is a diagram depicting an analysis 441B of scattering point density over an area of a coating having high oleophobicity. The analysis depicted in the diagram of FIG. 4D may be performed by the analyzer discussed previously herein with respect to FIG. 1. High oleophobicity of the coating may be substantially related to, and may be indicated by, scattering point sparseness 446 and/or absence 446 of any longitudinal pattern in scattering point density and/or absence 446 of any correlation pattern in scattering point density. High oleophobicity may be alternatively measurable by a water contact angle of approximately one hundred degrees or more. Density and/or sparsity of respective scattering points of a coating having high oleophobicity and a coating having low oleophobicity may be considered relative to each other. Scattering points of the coating having high oleophobicity may be substantially sparser than scattering points of the coating having low oleophobicity. Scattering points of the coating having low oleophobicity may be substantially denser than scattering points of the coating having high oleophobicity.

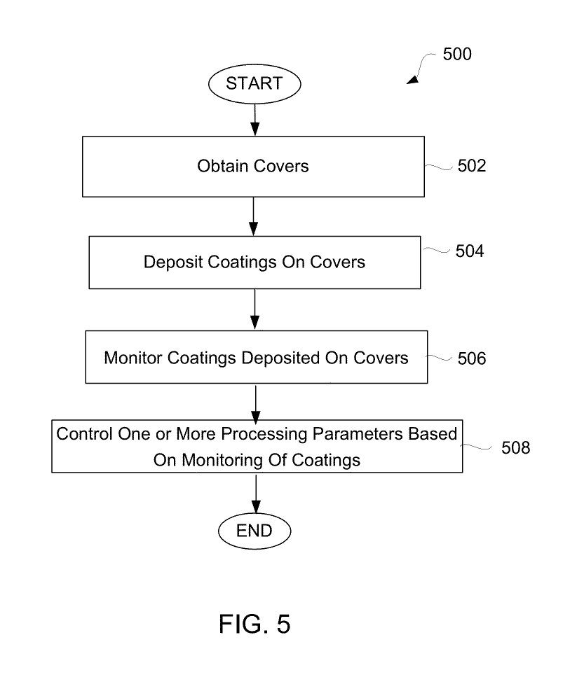

FIG. 5 is a flow diagram of a process 500 according to one embodiment. The process 500 can serve to produce covers for exposed surfaces of consumer electronic products. The process 500 can begin with obtaining covers 502 for the exposed surfaces of consumer electronic products. Glass covers or cover glass may be obtained, in one embodiment, after a glass sheet is singulated into glass pieces, (e.g., cover glass) and the edges of the cover glass are manipulated to have a predetermined geometry. The cover glass may be chemically strengthened cover glass. In other embodiments, the covers may be plastic or made from other materials.

The process can continue with depositing 504 coatings on the covers for exposed surfaces of consumer electronic products. The depositing 504 may comprise depositing an oleophobic coating.

The process 500 can further comprise monitoring 506 at least one of the coatings deposited on the covers for exposed surfaces of consumer electronic products. In particular, the monitoring 506 may comprise monitoring 506 the oleophobic coating.

Further, in one embodiment, dark field microscopy may be used in monitoring 506 at least one of the coatings. The coatings deposited on the covers may be illuminated using a dark field illuminator. As part of the monitoring 506, microscopic coating image data of scattering points over an area of at least one of the coatings may be collected.

Additionally, the monitoring 506 may comprise analyzing the microscopic coating image data of the scattering points, and determining scattering point density over the area of at least one of the coatings. This may comprise determining a longitudinal pattern in scattering point density over the area of at least one of the coatings, as discussed previously herein with reference to FIG. 4C. More specifically, this may comprise determining a correlation pattern in scattering point density over the area of at least one of the coatings, wherein the correlation pattern in scattering point density over the area of at least one of the coatings substantially correlates with a predetermined geometry feature of a conveyor mechanism.

As discussed previously herein with respect to FIG. 4C, low oleophobicity of the coating may be substantially related to, and may be indicated by, the longitudinal pattern in scattering point density and/or the correlation pattern in scattering point density. As discussed previously herein with respect to FIG. 4D, high oleophobicity of the coating may be substantially related to, and may be indicated by, scattering point sparseness and/or absence of any longitudinal pattern in scattering point density and/or absence of any correlation pattern in scattering point density.

The monitoring 506 may comprise generating a signal value that is substantially related to density of scattering points over an area of at least one of the coatings, and comparing a predetermined threshold value to the signal value that is substantially related to density of scattering points over the area of at least one of the coatings. As a result of this comparison, a monitor signal that is substantially related to oleophobicity of the coating may be generated by a comparator and may be received by a controller.

The process 500 may further comprise controlling 508 at least one processing parameter of the cover coating deposition assembly based at least in part on the monitoring. More generally, the depositing of the coating on the covers may be controlled, for example by the controller as discussed previously herein with reference to FIG. 1, based at least in part upon the monitoring of the coating. For example, a monitor signal indicating low oleophobicity of the coating may trigger the controller to drain and refill, so as to refresh, a supply of oleophobic ingredient of the cover coating deposition assembly. Similarly, the monitor signal indicating low oleophobicity of the coating may trigger the controller to control other or additional process parameters of the cover coating deposition assembly. Following the block 508, process 500 can end.

The techniques describe herein may be applied to glass surfaces used by any of a variety of electronic devices including but not limited handheld electronic devices, portable electronic devices and substantially stationary electronic devices. Examples of these include any known consumer electronic device that includes a display. By way of example, and not by way of limitation, the electronic device may correspond to media players, mobile phones (e.g., cellular phones), PDAs, remote controls, notebooks, tablet PCs, monitors, all in one computers and the like.

Some embodiments may be implemented by software, but can also be implemented in hardware or a combination of hardware and software. Some implementations may be embodied as computer readable code on a tangible computer readable medium. The tangible computer readable medium is any data storage device that can store data, which can thereafter be read by a computer system. Examples of tangible computer readable medium include read-only memory, random-access memory, CD-ROMs, DVDs, magnetic tape, and optical data storage devices.

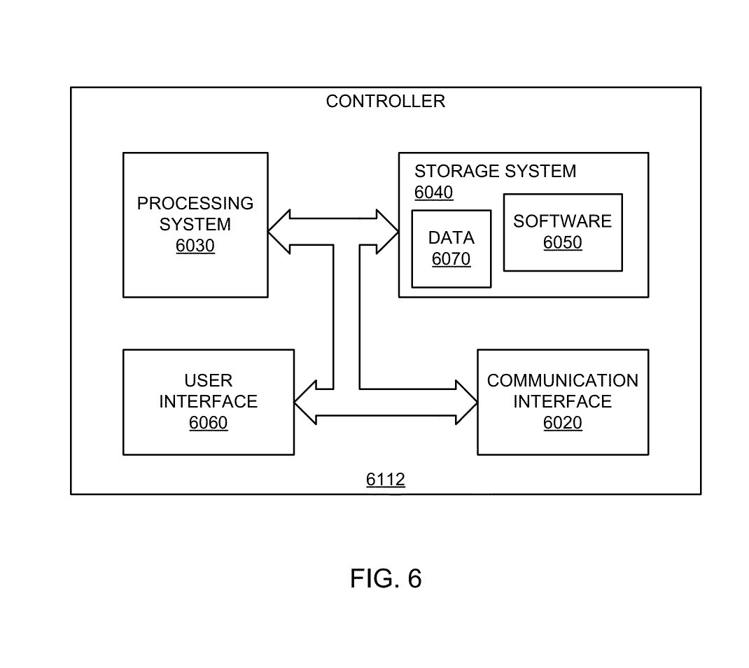

FIG. 6 is a block diagram of a controller 6112 according to one embodiment. Controller 6112 can includes communication interface 6020, processing system 6030, storage system 6040, and user interface 6060. Processing system 6030 can be operatively coupled to storage system 6040. Storage system 6040 can store software 6050 and data 6070.

This application references U.S. patent application Ser. No. 13/024,964 filed Feb. 10, 2011, and entitled “Direct Liquid Vaporization For Oleophobic Coatings”, which is hereby incorporated herein by reference.

The various aspects, features, embodiments or implementations of the invention described above can be used alone or in various combinations.

Different aspects, embodiments or implementations may, but need not, yield one or more of the following advantages. One advantage is that automating control and/or monitoring coatings may provide for greater efficiency and/or more consistent quality in coatings. Another advantage is that tighter tolerances for oleophobicity of oleophobic coatings may be employed. Another advantage is that cover coating deposition assemblies may be better managed.

Although only a few embodiments of the invention have been described, it should be understood that the invention may be embodied in many other specific forms without departing from the spirit or scope of the present invention. By way of example, the steps associated with the methods of the invention may vary widely. Steps may be added, removed, altered, combined, and reordered without departing from the spirit or scope of the invention. Similarly, while operations are depicted in the drawings in a particular order, this should not be understood as requiring that such operations be performed in the particular order shown or in sequential order, or that all illustrated operations be performed, to achieve desirable results.

While this specification contains many specifics, these should not be construed as limitations on the scope of the disclosure or of what may be claimed, but rather as descriptions of features specific to particular embodiment of the disclosure. Certain features that are described in the context of separate embodiments can also be implemented in combination. Conversely, various features that are described in the context of a single embodiment can also be implemented in multiple embodiments separately or in any suitable subcombination. Moreover, although features may be described above as acting in certain combinations, one or more features from a claimed combination can in some cases be excised from the combination, and the claimed combination may be directed to a subcombination or variation of a subcombination.

While this invention has been described in terms of several embodiments, there are alterations, permutations, and equivalents, which fall within the scope of this invention. It should also be noted that there are many alternative ways of implementing the methods and apparatuses of the present invention. It is therefore intended that the following appended claims be interpreted as including all such alterations, permutations, and equivalents as fall within the true spirit and scope of the present invention.

What is claimed is:

1. A system for producing covers for exposed surfaces of consumer electronic products comprising:
a cover coating deposition assembly configured to deposit coatings on the covers for exposed surfaces of consumer electronic products; and
a cover coating monitor configured to monitor the coatings deposited on the covers for exposed surfaces of consumer electronic products.

2. A system as recited in claim 1 wherein:
the coatings comprise an oleophobic ingredient; and
the cover coating monitor is configured to monitor the coatings comprising the oleophobic ingredient.

3. A system as recited in claim 1 wherein the cover coating monitor comprises an illuminator.

4. A system as recited in claim 1 wherein the cover coating monitor comprises a dark field illuminator.

5. A system as recited in claim 1 wherein the cover coating monitor comprises an electronic camera optically coupled with the coating for collecting microscopic coating image data of scattering points over an area of the coating.

6. A system as recited in claim 5 wherein the cover coating monitor further comprises a scattering point density analyzer coupled with the electronic camera and configured to analyze the microscopic coating image data of the scattering points, so as to determine scattering point density over the area of the coating.

7. A system as recited in claim 5 wherein the cover coating monitor further comprises a scattering point density analyzer coupled with the electronic camera and configured to analyze the microscopic coating image data of the scattering points, so as to determine a longitudinal pattern in scattering point density over the area of the coating.

8. A system as recited in claim 5 further comprising a conveyor mechanism having a predetermined geometry feature, wherein the conveyor mechanism is configured to convey the covers,
wherein the cover coating monitor further comprises a scattering point density analyzer coupled with the electronic camera and configured to analyze the microscopic coating image data of the scattering points, so as to determine a correlation pattern in scattering point density over the area of the coating, and
wherein the correlation pattern in scattering point density over the area of the coating substantially correlates with the predetermined geometry feature of the conveyor mechanism.

9. A system as recited in claim 1 wherein the cover coating monitor comprises a comparator for comparing at least one predetermined threshold value and a signal value that is substantially related to density of scattering points over an area of the coating.

10. A system as recited in claim 1 further comprising a controller coupled with the cover coating monitor for receiving a monitor signal that is substantially related to oleophobicity of the coating.

11. A system as recited in claim 1 further comprising a controller coupled with the cover coating deposition assembly for controlling at least one processing parameter of the cover coating deposition assembly.

12. A system as recited in claim 1 further comprising a controller, wherein:
the controller is coupled with the cover coating monitor for receiving a monitor signal that is substantially related to oleophobicity of the coating; and
the controller is adapted for generating an indicator signal when the oleophobicity of the coating provided by the cover coating deposition assembly should be adjusted based at least in part on the monitor signal.

13. A system as recited in claim 1 further comprising a controller, wherein:
the controller is coupled with the cover coating monitor for receiving a monitor signal that is substantially related to oleophobicity of the coating; and
the controller is coupled with the cover coating deposition assembly for controlling at least one processing parameter of the cover coating deposition assembly based at least in part on the monitor signal.

14. A consumer electronic product, comprising:
a housing having a front surface;
electrical components provided at least partially internal to the housing, the electrical components including at least a processor, a memory, and a display, the display being provided at or adjacent the front surface of the housing; and
a cover provided at or over the front surface of the housing such that it is provided over the display, the cover being coated using a monitored oleophobic coating.

15. A consumer electronic product as recited in claim 14, wherein the consumer electronic product is a handheld electronic device.

16. A consumer electronic product as recited in claim 14, wherein depth of the monitored oleophobic coating is approximately ten nanometers or more.

17. A consumer electronic product as recited in claim 14, wherein the monitored oleophobic coating has oleophobicity measurable by a water contact angle of approximately one hundred degrees or more.

18. A consumer electronic product as recited in claim 14 wherein the cover comprises chemically strengthened glass.

19. A method for producing covers for exposed surfaces of consumer electronic products, the method comprising:
obtaining covers for the exposed surfaces of consumer electronic products;
depositing coatings on the covers for exposed surfaces of consumer electronic products; and
monitoring at least one of the coatings deposited on the covers for exposed surfaces of consumer electronic products.

20. A method as recited in claim 19, wherein:
the depositing comprises depositing an oleophobic coating; and
the monitoring comprises monitoring the oleophobic coating.

21. A method as recited in claim 19 wherein the monitoring comprises illuminating the coatings deposited on the covers using a dark field illuminator.

22. A method as recited in claim 19 wherein the monitoring comprises dark field microscopy.

23. A method as recited in claim 19 wherein the monitoring comprises collecting microscopic coating image data of scattering points over an area of at least one of the coatings.

24. A method as recited in claim 23 wherein monitoring further comprises: analyzing the microscopic coating image data of the scattering points; and determining scattering point density over the area of at least one of the coatings.

25. A method as recited in claim 23 wherein the monitoring further comprises: analyzing the microscopic coating image data of the scattering points; and determining a longitudinal pattern in scattering point density over the area of at least one of the coatings.

26. A method as recited in claim 23 further comprising conveying the covers for exposed surfaces of consumer electronic products using a conveyor mechanism, wherein the conveyor mechanism has a predetermined geometry feature, and
wherein the monitoring further comprises:
analyzing the microscopic coating image data of the scattering points; and determining a correlation pattern in scattering point density over the area of at least one of the coating, wherein the correlation pattern in scattering point density over the area of at least one of the coatings substantially correlates with the predetermined geometry feature of the conveyor mechanism.

27. A method as recited in claim 19 wherein the monitoring comprises:
generating a signal value that is substantially related to density of scattering points over an area of at least one of the coatings; and
comparing a predetermined threshold value to the signal value that is substantially related to density of scattering points over the area of at least one of the coatings.

28. A method as recited in claim 19 further comprising controlling the depositing of the coating on the covers based at least in part upon the monitoring of the coating.

29. A method as recited in claim 19 further comprising receiving a monitor signal that is substantially related to oleophobicity of the coating.

30. A method as recited in claim 29 further comprising controlling the depositing of the coating on the covers based at least upon receiving the monitor signal that is substantially related to oleophobicity of the coating.

31. A method as recited in claim 30 wherein the controlling comprises:
determining, based at least in part on the monitor signal, that there is to be adjustment of oleophobicity, which is provided by the depositing of the coatings on the covers; and
adjusting oleophobicity provided by the depositing of the coatings on the covers.
